(19) United States
(12) Patent Application Publication
(10) Pub. No.: US 2026/0321540 A1
(43) Pub. Date: Oct. 15, 2026

(54) ANTENNA DEVICE AND PLASMA PROCESSING DEVICE

(71) Applicant: NISSIN ELECTRIC CO., LTD., Kyoto (JP)

(72) Inventors: Satoru NAGAMACHI, Kyoto (JP); Ryota ANDO, Kyoto (JP); Natsuo TATSUMI, Kyoto (JP); Yoshihide NAKAJIRI, Kyoto (JP); Yasunori ANDO, Kyoto (JP)

(73) Assignee: NISSIN ELECTRIC CO., LTD., Kyoto (JP)

(21) Appl. No.: 19/104,365

(22) PCT Filed: Dec. 28, 2023
(86) PCT No.: PCT/JP2023/047256

§ 371 Date: Feb. 18, 2025

(30) Foreign Application Priority Data
Jan. 13, 2023 (JP) 2023-003845

(51) Int. Cl. H01J 37/32

(52) U.S. Cl. CPC H01J 37/3211

(57) ABSTRACT

An antenna device for flowing a high-frequency current to generate plasma includes: an antenna forming a straight line shape; an insulating cover covering an outer circumferential surface of the antenna and forming a straight tube shape; and a protruding insulating part that is provided between both axial ends of the antenna protrudes to an inner circumferential surface side of the insulating cover beyond the outer circumferential surface of the antenna, and is composed of an insulating material.

### TECHNICAL FIELD

The present invention relates to an antenna device for flowing a high-frequency current to generate inductively coupled plasma, and a plasma processing device including this antenna device.

### RELATED ART

Conventionally, a plasma processing device has been proposed to flow a high-frequency current through an antenna, generate inductively coupled plasma (abbreviated as ICP) by an induced electric field generated therefrom, and perform processing on a substrate using the inductively coupled plasma.

In this type of plasma processing device, an antenna device including an antenna in a straight line shape and an insulating cover covering the antenna has been proposed. Upon lengthening the antenna to be compatible with large substrates and the like, there is a possibility that the antenna may bend. Thus, a nut having an outer diameter larger than an outer diameter of the antenna is fitted externally to the antenna. Accordingly, even if the antenna bends, the nut can prevent the antenna from contacting the insulating cover.

### RELATED ART DOCUMENTS

### Patent Documents

Patent Document 1: Japanese Patent Application Laid-Open No. 2019-160593

### SUMMARY OF INVENTION

### Problem to Be Solved by Invention

However, in the case of performing plasma processing using such an antenna device, since the outer diameter of the nut is larger than the outer diameter of the antenna, the electric field concentrates at a protruding portion of the nut. As a result, in the case of performing plasma processing, ions in the plasma may collide with the insulating cover near the protruding portion of the nut, so the insulating cover may be etched and damaged.

Thus, the present invention has been made to solve the above problem, and a main objective thereof is to prevent damage to an insulating cover even in the case of lengthening an antenna to perform plasma processing.

### Means for Solving Problem

Namely, an antenna device according to the present invention is an antenna device for flowing a high-frequency current to generate plasma. The antenna device includes an antenna, an insulating cover, and a protruding insulating part. The antenna forms a straight line shape. The insulating cover covers an outer circumferential surface of the antenna and forms a straight tube shape. The protruding insulating part is provided between both axial ends of the antenna, protrudes to an inner circumferential surface side of the insulating cover beyond the outer circumferential surface of the antenna, and is composed of an insulating material.

With this configuration, since the electric field does not concentrate at the protruding insulating part, ions in the plasma do not collide with the insulating cover near the protruding insulating part, and the insulating cover can be prevented from being etched and damaged.

In addition, even in the case where the antenna or the insulating cover bends, contact between the antenna and the insulating cover can be avoided by the protruding insulating part.

Upon lengthening the antenna, bending is likely to occur. As a specific example of an antenna that is particularly likely to bend, the antenna is an LC antenna further including: at least two conductor elements; an insulating element provided between the conductor elements adjacent to each other to insulate the conductor elements; and a capacitive element electrically connected in series with the conductor elements adjacent to each other.

With this configuration, even with an LC antenna which is likely to bend, contact between the antenna and the insulating cover can be avoided by the protruding insulating part.

In addition, since the capacitive element is electrically connected in series with the pair of conductor elements, a combined reactance of the antenna can be configured in a form obtained by subtracting a capacitive reactance from an inductive reactance. As a result, an impedance of the antenna can be reduced, and even in the case where the antenna is lengthened, an increase in an impedance thereof is suppressed, it becomes easier for high-frequency current to flow through the antenna, and uniform plasma can be efficiently generated.

In the antenna device, an accommodating recess accommodating an insulator constituting the protruding insulating part is preferably formed on the outer circumferential surface of the antenna.

With this configuration, since the protruding insulating part is provided in the accommodating recess, movement of the protruding insulating part in the axial direction is restricted within the accommodating recess. Thus, by providing the accommodating recess at a spot at which the antenna is likely to bend, contact between the antenna and the insulating cover can be further avoided.

Since bending of the antenna is likely to occur at a connection portion of the conductor element and the insulating element, in the antenna device, the accommodating recess is preferably formed between an axial end face of the conductor element and an axial end face of the insulating element.

With this configuration, since the protruding insulating part is provided at a spot at which bending is likely to occur, contact between the antenna and the insulating cover can be further avoided.

In the antenna device, the accommodating recess is desirably formed on an outer circumferential surface of the conductor element.

With this configuration, since the protruding insulating part is provided separated from the insulating element, contact between the protruding insulating part and the insulating element in the axial direction can be prevented, and temperature influence of the protruding insulating part on the insulating element can be suppressed. As a result, since occurrence of a temperature difference in the insulating element can be prevented, damage to the insulating element can be prevented.

In addition, a plasma processing device according to the present invention includes: the antenna described above; a vacuum vessel inside which or outside which the antenna is disposed; and a high-frequency power supply applying a high-frequency current to the antenna.

With a plasma processing device configured in this manner, since damage to the insulating cover is prevented as described above, quality of a thickness of the film and the like can be ensured, and reliability can be improved.

### Effects of Invention

According to the present invention configured in this manner, damage to the insulating cover can be prevented even in the case where the antenna is lengthened to perform plasma processing.

### BRIEF DESCRIPTION OF THE DRAWINGS

FIG. 1 is a vertical cross-sectional view schematically showing a configuration of a plasma processing device of the present embodiment.

FIG. 2 is an enlarged cross-sectional view schematically showing a peripheral configuration of an antenna device of the same embodiment.

FIG. 3 is an enlarged cross-sectional view schematically showing a peripheral configuration of a protruding insulating part of the same embodiment.

FIG. 4 is a cross-sectional view taken along a line A-A of the peripheral configuration of the protruding insulating part of the same embodiment.

FIG. 5 is an enlarged cross-sectional view schematically showing a peripheral configuration of a protruding insulating part of a modification embodiment.

FIG. 6 is a cross-sectional view taken along a line A-A of a peripheral configuration of a protruding insulating part of a modification embodiment.

FIG. 7 is an enlarged cross-sectional view schematically showing a peripheral configuration of a protruding insulating part of a modification embodiment.

### DESCRIPTION OF THE EMBODIMENTS

Hereinafter, an embodiment of a plasma processing device according to the present invention will be described with reference to the drawings. In any of the figures illustrated below, portions may be omitted as appropriate or exaggerated and schematically depicted for clarity. Same constituent elements will be labeled with same reference signs, with descriptions thereof omitted as appropriate.

### Device Configuration

A plasma processing device 100 of the present embodiment applies a processing to a substrate W using inductively coupled plasma P. Herein, the substrate W is, for example, a substrate for a flat panel display (FPD) such as a liquid crystal display or an organic EL display, a flexible substrate for a flexible display, etc. In addition, the processing applied to the substrate W includes, for example, film formation by a plasma CVD method, etching, ashing, sputtering, etc.

The plasma processing device 100 is also referred to as a plasma CVD device in the case of performing film formation by the plasma CVD method, as a plasma etching device in the case of performing etching, as a plasma ashing device in the case of performing ashing, and as a plasma sputtering device in the case of performing sputtering.

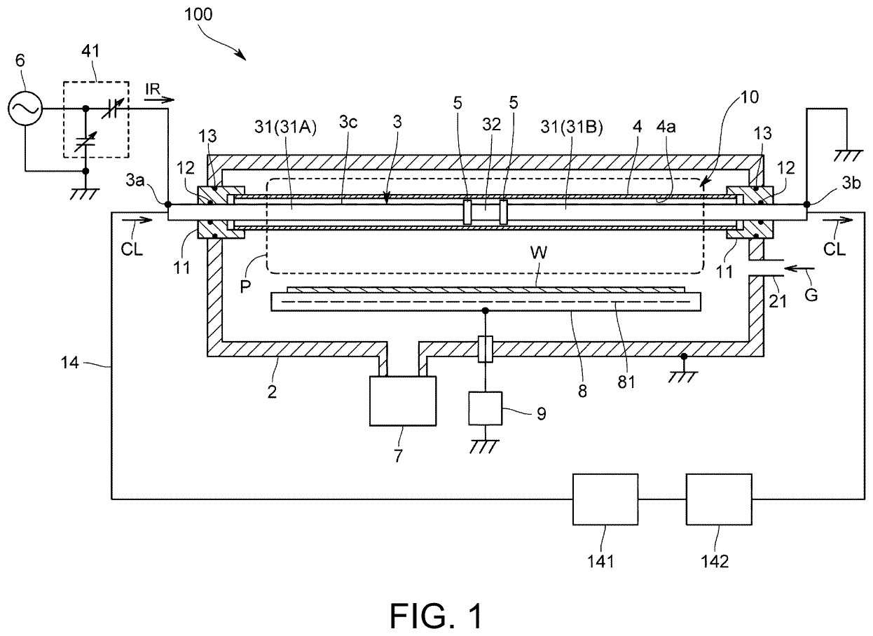

Specifically, as shown in FIG. 1, the plasma processing device 100 includes: a vacuum vessel 2 that is vacuum exhausted and into which a gas G is introduced; an antenna 3 in a straight line shape disposed inside the vacuum vessel 2; an insulating cover 4 forming a straight tube shape; a protruding insulating part 5 composed of an insulating material; and a high-frequency power supply 6 that applies a high frequency to the antenna 3 to generate inductively coupled plasma P inside the vacuum vessel 2. By applying a high frequency from the high-frequency power supply 6 to the antenna 3, a high-frequency current IR flows through the antenna 3, and an induced electric field is generated inside the vacuum vessel 2 to generate the inductively coupled plasma P. In addition, in the present embodiment, an antenna device 10 is constituted by the antenna 3, the insulating cover 4, and the protruding insulating part 5.

The vacuum vessel 2 is, for example, a vessel made of metal, and an inside thereof is vacuum exhausted by a vacuum exhaust device 7. In this example, the vacuum vessel 2 is electrically grounded.

A gas G is introduced into the vacuum vessel 2, for example, via a flow regulator (not shown) and multiple gas introduction ports 21 formed at a sidewall of the vacuum vessel 2. The gas G may be selected according to a processing content applied to the substrate W. For example, in the case of performing film formation on the substrate W by the plasma CVD method, the gas G is a raw material gas or a gas obtained by diluting the raw material gas with a dilution gas (e.g., H₂). As more specific examples, in the case where the raw material gas is SiH₄, a Si film can be formed on the substrate W; in the case where the raw material gas is SiH₄+NH₃, a SiN film can be formed on the substrate W; in the case where the raw material gas is SiH₄+O₂, a SiO₂ film can be formed on the substrate W; and in the case where the raw material gas is SiF₄+N₂, a SiN:F film (fluorinated silicon nitride film) can be formed on the substrate W.

In addition, a substrate holder 8 holding the substrate W is provided inside the vacuum vessel 2. As in this example, a bias voltage may be applied to the substrate holder 8 from a bias power supply 9. The bias voltage may be, for example, a negative DC voltage or a negative pulse voltage, but is not limited thereto. With such a bias voltage, it is possible to control, for example, energy of positive ions in the plasma P when incident on the substrate W, to perform control on a degree of crystallization of the film formed on a surface of the substrate W. A heater 81 heating the substrate W may also be provided inside the substrate holder 8.

The antenna 3 is disposed along the surface of the substrate W (e.g., substantially parallel to the surface of the substrate W), above the substrate W inside the vacuum vessel 2. The antenna 3 disposed inside the vacuum vessel 2 may be one antenna or may be multiple antennas.

Vicinities of both ends of the antenna 3 respectively penetrate through opposing sidewalls of the vacuum vessel 2. Insulating members 11 are respectively provided at portions at which the both ends of the antenna 3 penetrate to outside of the vacuum vessel 2. The both ends of the antenna 3 penetrate through the respective insulating members 11, and penetrated parts thereof are vacuum-sealed, for example, by packings 12. Packings 13, for example, also vacuum-seal between each insulating member 11 and the vacuum vessel 2. A material of the insulating member 11 is, for example, ceramics such as alumina, quartz, or engineering plastics such as polyphenylene sulfide (PPS), polyetheretherketone (PEEK), etc.

Furthermore, the portion of the antenna 3 located inside the vacuum vessel 2 is covered by the insulating cover 4 in a straight tube shape. Both ends of the insulating cover 4 are supported by the insulating members 11. It is not necessarily required to seal between the both ends of the insulating cover 4 and the insulating members 11. This is because even if the gas G enters a space inside the insulating cover 4, the plasma P does not usually occur in the space since the space is small and an electron travel distance is short. A material of the insulating cover 4 is, for example, quartz, alumina, fluororesin, silicon nitride, silicon carbide, silicon, etc.

By providing the insulating cover 4, it is possible to suppress incidence of charged particles in the plasma P onto a metal pipe 31 constituting the antenna 3. Thus, it is possible to suppress a rise in a plasma potential resulting from incidence of charged particles (mainly electrons) onto the metal pipe 31, and it is possible to suppress occurrence of metal contamination with respect to the plasma P and the substrate W due to sputtering of the metal pipe 31 by charged particles (mainly ions).

The high-frequency power supply 6 is connected to a power supply end 3a, which is one end of the antenna 3, via a matching circuit 41, and a terminal 3b, which is the other end, is directly grounded. The power supply end 3a may also be connected to the high-frequency power supply 6 via a capacitor, a coil, etc., and the terminal 3b may also be grounded via a capacitor, a coil, etc.

With the above configuration, a high-frequency current IR can be flowed to the antenna 3 from the high-frequency power supply 6 via the matching circuit 41. A frequency of the high-frequency current IR is, for example, generally 13.56 MHz, but is not limited thereto.

The antenna 3 is a hollow structure having a flow path therein through which a cooling liquid CL circulates. The cooling liquid CL circulates through the antenna 3 via a circulation path 14 provided outside the vacuum vessel 2. The circulation path 14 is provided with a temperature adjustment mechanism 141 such as a heat exchanger for adjusting the cooling liquid CL to a constant temperature, and a circulation mechanism 142 such as a pump for circulating the cooling liquid CL in the circulation path 14. From the viewpoint of electrical insulation, the cooling liquid CL is preferably high-resistance water, and is preferably, for example, pure water or water close to pure water. Alternatively, a liquid coolant other than water, such as a fluorine-based inert liquid, may also be used.

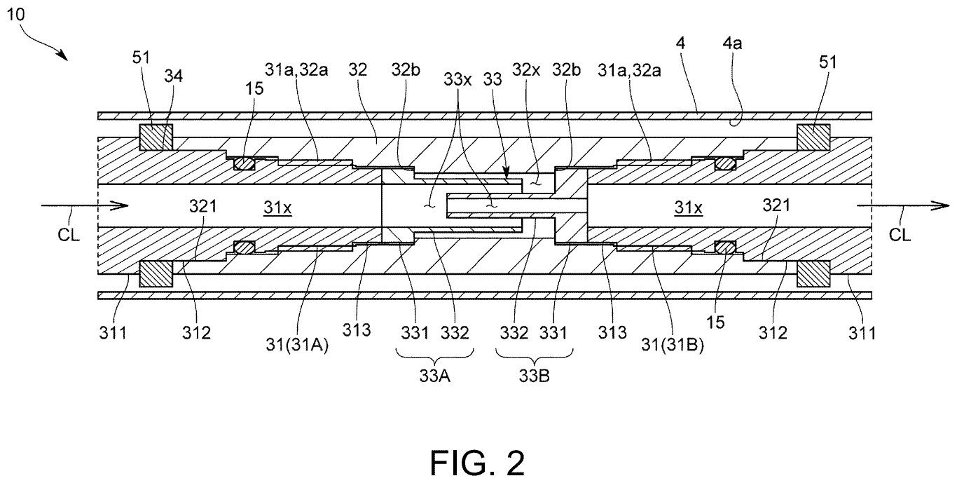

Specifically, as shown in FIG. 2, the antenna 3 includes at least two conductor elements 31 (hereinafter referred to as “metal pipes 31”) made of metal forming a tubular shape, an insulating element 32 (hereinafter referred to as an “insulating pipe 32”) in a tubular shape provided between the metal pipes 31 adjacent to each other to insulate the metal pipes 31, and a capacitor 33 which is a capacitive element electrically connected in series with the metal pipes 31 adjacent to each other.

In the present embodiment, a quantity of the metal pipes 31 is two, and quantities of the insulating pipe 32 and the capacitor 33 are respectively one. In the following description, one of the metal pipes 31 is also referred to as a “first metal pipe 31A”, and the other of the metal pipes is also referred to as a “second metal pipe 31B”. The antenna 3 may also have a configuration with three or more metal pipes 31, and in that case, the quantities of the insulating pipe 32 and the capacitor 33 will each be one less than the quantity of the metal pipes 31.

The metal pipe 31 has a straight tube shape formed with a flow path 31x therein in a straight line shape through which the cooling liquid CL flows. A material of the metal pipe 31 is, for example, copper, aluminum, an alloy thereof, stainless steel, etc.

In addition, a male screw part 31a is formed at an outer circumferential part of at least one longitudinal end of the metal pipe 31. To achieve commonality of components with a configuration that connects multiple metal pipes 31, the male screw part 31a is desirably formed at both longitudinal ends of the metal pipe 31 to provide interchangeability.

The insulating pipe 32 has a straight tube shape formed with a flow path 32x therein in a straight line shape through which the cooling liquid CL flows. A material of the insulating pipe 32 is, for example, alumina, fluororesin, polyethylene (PE), engineering plastics (e.g., polyphenylene sulfide (PPS) and polyetheretherketone (PEEK)), etc.

Furthermore, a female screw part 32a to be screwed and connected with the male screw part 31a of the metal pipe 31 is formed on an inner circumferential surface of the insulating pipe 32. In addition, on an inner wall of the insulating pipe 32, recesses 32b for fitting a pair of electrodes 33A and 33B constituting the capacitor 33 are formed over an entire circumferential direction, on an axial center side compared to the respective female screw parts 32a. In the present embodiment, the insulating pipe 32 is formed from one member, but may also be formed by joining multiple members.

The capacitor 33 is provided inside the insulating pipe 32, and specifically, is provided inside the flow path 32x of the insulating pipe 32 through which the cooling liquid CL flows.

Specifically, the capacitor 33 includes a first electrode 33A that is electrically connected to one (first metal pipe 31A) of the metal pipes 31 adjacent to each other, and a second electrode 33B that is electrically connected to the other (second metal pipe 31B) of the metal pipes 31 adjacent to each other and is disposed opposed to the first electrode 33A. The capacitor 33 is configured such that the cooling liquid CL fills up a space between the first electrode 33A and the second electrode 33B. In other words, the cooling liquid CL flowing through the space between the first electrode 33A and the second electrode 33B serves as a dielectric constituting the capacitor 33.

Each of the electrodes 33A and 33B forms a substantially rotational body shape, and is formed with a main flow path 33x at a central part along a central axis thereof. Specifically, each of the electrodes 33A and 33B has a flange part 331 that electrically contacts an end of the metal pipe 31 on the insulating pipe 32 side, and an extension part 332 that extends from the flange part 331 to the insulating pipe 32 side. Each of the electrodes 33A and 33B may have the flange part 331 and the extension part 332 formed from one member, or formed by separate parts joined together. A material of the electrodes 33A and 33B is, for example, aluminum, copper, an alloy thereof, etc.

The flange part 331 contacts the end of the metal pipe 31 on the insulating pipe 32 side over the entire circumferential direction. Specifically, an axial end face of the flange part 331 contacts a tip face of a contact part 313 in a cylindrical shape formed at the end of the metal pipe 31 over the entire circumferential direction.

The extension part 332 forms a cylindrical shape and is formed with a main flow path 33x therein. The extension part 332 of the first electrode 33A and the extension part 332 of the second electrode 33B are disposed coaxially with each other. In other words, the extension parts 332 are provided in a state in which the extension part 332 of the second electrode 33B is inserted into the extension part 332 of the first electrode 33A. Accordingly, a cylindrical space along the flow path direction is formed between the extension part 332 of the first electrode 33A and the extension part 332 of the second electrode 33B.

Each of the electrodes 33A and 33B configured in this manner is fitted to the recess 32b formed on the inner wall of the insulating pipe 32. Specifically, the first electrode 33A is fitted to the recess 32b formed on one axial end side of the insulating pipe 32, and the second electrode 33B is fitted to the recess 32b formed on the other axial end side of the insulating pipe 32. By fitting each of the electrodes 33A and 33B to each recess 32b in this manner, the extension part 332 of the first electrode 33A and the extension part 332 of the second electrode 33B are disposed coaxially with each other. In addition, with the end face of the flange part 331 of each of the electrodes 33A and 33B contacting a surface of each recess 32b facing an axial outer side, an insertion dimension of the extension part 332 of the second electrode 33B with respect to the extension part 332 of the first electrode 33A is defined.

In addition, by fitting each of the electrodes 33A and 33B to each recess 32b of the insulating pipe 32, and screwing the male screw part 31a of the metal pipe 31 into the female screw part 32a of the insulating pipe 32, the tip face of the contact part 313 of the metal pipe 31 contacts the flange part 331 of the electrodes 33A and 33B, and each of the electrodes 33A and 33B is clamped and fixed between the insulating pipe 32 and the metal pipe 31. In this manner, the antenna 3 of the present embodiment has a structure in which the metal pipes 31, the insulating pipe 32, the first electrode 33A, and the second electrode 33B are disposed coaxially.

In this configuration, upon flowing of the cooling liquid CL from the first metal pipe 31A, the cooling liquid CL flows to the second electrode 33B side through the main flow path 33x of the first electrode 33A. The cooling liquid CL that has flowed to the second electrode 33B side flows to the second metal pipe 31B through the main flow path 33x of the second electrode 33B. At this time, the cylindrical space between the extension part 332 of the first electrode 33A and the extension part 332 of the second electrode 33B is filled up with the cooling liquid CL, and the cooling liquid CL serves as a dielectric and constitutes the capacitor 33.

Furthermore, in the present embodiment, a connection part between the metal pipe 31 and the insulating pipe 32 has a seal structure with respect to vacuum and the cooling liquid CL. The seal structure is realized by a seal member 15 such as a packing provided at a base end of the male screw part 31a, but a taper screw structure for a pipe may also be used, for example.

With the configuration described above, the seal structure between the metal pipe 31 and the insulating pipe 32, and electrical contact between the metal pipe 31 and each of the electrodes 33A and 33B are performed together with the fastening of the male screw part 31a and the female screw part 32a, so the assembly work is very simple.

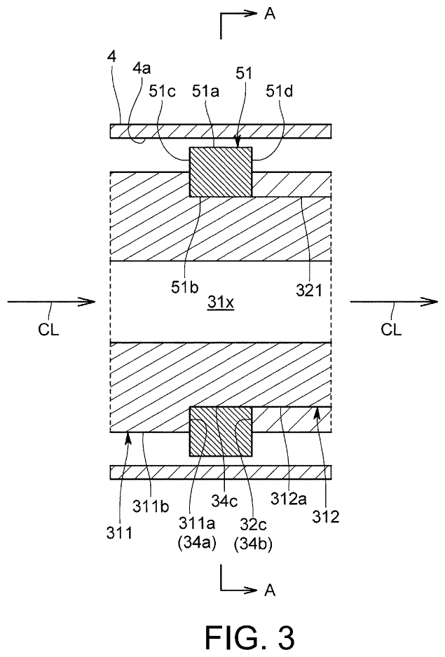

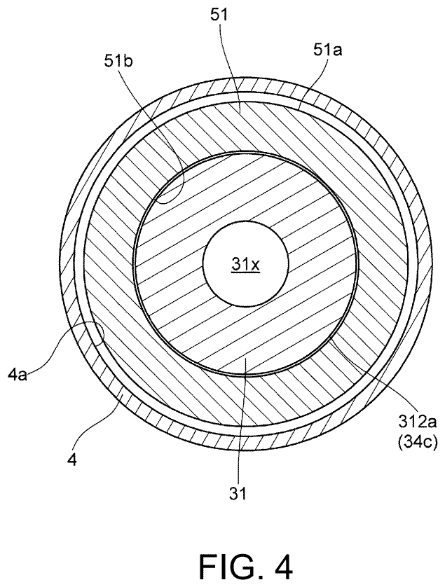

The antenna device 10 of the present embodiment further includes a protruding insulating part 5 that is composed of an insulating material, is provided between both axial ends 3a and 3b of the antenna 3, and protrudes to an inner circumferential surface 4a side of the insulating cover 4 beyond an outer circumferential surface 3c of the antenna 3. Specifically, the protruding insulating part 5 is provided on the outer circumferential surface 3c of the antenna 3 covered by the insulating cover 4, and protrudes from the outer circumferential surface 3c of the antenna 3. More specifically, as shown in FIG. 3 and FIG. 4, an insulator 51 constituting the protruding insulating part 5 forms an annular shape, and an outer circumferential surface 51a of the insulator 51 is located on the inner circumferential surface 4a side of the insulating cover 4 compared to the outer circumferential surface 3c of the antenna 3. Accordingly, contact between the antenna 3 and the insulating cover 4 is avoided even if the antenna 3 bends. The insulating material is, for example, high-melting-point ceramics such as quartz or alumina, and is preferably a material that is less likely to deform even in the case of performing long-time plasma processing.

In addition, an accommodating recess 34 accommodating the insulator 51 is formed on the outer circumferential surface 3c of the antenna 3. Specifically, the accommodating recess 34 is formed on the outer circumferential surface 3c of the antenna 3 covered by the insulating cover 4, and in the present embodiment, is provided between an axial end face 311a of the metal pipe 31 and an axial end face 32c of the insulating pipe 32.

More specifically, the metal pipe 31 has a large-diameter part 311, and a small-diameter part 312 that is formed on the axial end face 311a of the large-diameter part 311 and extends in the axial direction. In addition, the insulating pipe 32 has an insertion recess 321 that is formed on the axial end face 32c, extends in the axial direction, and into which the small-diameter part 312 is inserted. With this configuration, the accommodating recess 34 is formed by the axial end face 311a of the large-diameter part 311, the outer circumferential surface 312a of the small-diameter part 312, and the axial end face 32c of the insulating pipe 32. In other words, the axial end face 311a of the large-diameter part 311 and the axial end face 32c of the insulating pipe 32 respectively form opposing surfaces 34a and 34b that are opposed to end faces 51c and 51d of the insulator 51, and the outer circumferential surface 312a of the small-diameter part 312 forms a bottom surface 34c of the accommodating recess 34.

The insulator 51 is attached to the accommodating recess 34. Specifically, the insulator 51 is attached to the metal pipe 31 by moving along the outer circumferential surface 312a of the small-diameter part 312 to the axial end face 311a of the large-diameter part 311. Subsequently, by inserting the small-diameter part 312 into the insertion recess 321, the insulator 51 is provided in the accommodating recess 34.

With the insulator 51 attached to the accommodating recess 34, the inner circumferential surface 51b of the insulator 51 contacts the outer circumferential surface 312a of the small-diameter part 312, a part of one end face 51c of the insulator 51 contacts the axial end face 311a of the large-diameter part 311, and a part of the other end face 51d contacts the axial end face 32c of the insulating pipe 32. Accordingly, the insulator 51 is fixed in the accommodating recess 34 in the axial direction. In addition, since the insulator 51 forms an annular shape and is provided over the outer circumferential surface 312a of the small-diameter part 312, bending of the antenna 3 is suppressed by the insulator 51 restricting radial movement of the small-diameter part 312.

In addition, in this state, radial lengths of the end faces 51c and 51d of the insulator 51 are configured to be longer than radial lengths of the axial end faces 311a and 32c. Accordingly, the end faces 51c and 51d of the insulator 51 protrude with respect to the axial end faces 311a and 32c, and the outer circumferential surface 51a of the insulator 51 is located on the inner circumferential surface 4a side of the insulating cover 4 compared to the outer circumferential surface 311b of the large-diameter part 311. In other words, the protruding insulating part 5 is constituted by a protruding portion of the outer circumferential surface 51a and the end faces 51c and 51d of the insulator 51.

### Experimental Example

In the plasma processing device 100 of the present embodiment, when a high frequency was applied to the antenna 3 to generate Ar plasma (15 Pa, 3 kW), the Ar plasma was stably ignited for 1000 hours. In contrast, in a conventional plasma processing device, when a high frequency was applied to an antenna to generate Ar plasma (15 Pa, 3 kW), a hole was opened at an insulating cover in the vicinity of a butted part of a metal pipe 31 and an insulating pipe 32 after about 400 cumulative hours, and a capacitive element was damaged.

### Effects of Present Embodiment

According to the present embodiment, since the electric field does not concentrate at the protruding insulating part 5, ions in the plasma do not collide with the insulating cover 4 near the protruding insulating part 5, and the insulating cover 4 can be prevented from being etched and damaged. In addition, even in the case where the antenna 3 or the insulating cover 4 bends, contact between the antenna 3 and the insulating cover 4 can be avoided by the protruding insulating part 5.

According to the present embodiment, the antenna 3 is an LC antenna including the conductor elements 31, the insulating element 32, and the capacitor 33 which is a capacitive element. Thus, the capacitor 33 is electrically connected to the pair of conductor elements 31, and a combined reactance of the antenna 3 can be configured in a form obtained by subtracting a capacitive reactance from an inductive reactance. As a result, an impedance of the antenna 3 can be reduced, and even in the case of lengthening the antenna 3, an increase in the impedance thereof can be suppressed, it becomes easier for a high-frequency current to flow through the antenna 3, and uniform plasma can be efficiently generated.

According to the present embodiment, since the protruding insulating part 5 is provided in the accommodating recess 34, movement of the protruding insulating part 5 in the axial direction is restricted within the accommodating recess 34. Accordingly, by providing the accommodating recess 34 at a spot at which the antenna 3 is likely to bend, contact between the antenna 3 and the insulating cover 4 can be avoided.

In particular, according to the present embodiment, since the antenna 3 is an LC antenna, in the case where the antenna 3 is lengthened, bending is likely to occur at the connection portion of the metal pipe 31 and the insulating pipe 32. Herein, the accommodating recess 34 is provided between the axial end face 311a of the metal pipe 31 and the axial end face 32c of the insulating pipe 32, and the insulator 51 is accommodated in the accommodating recess 34. Thus, even in the case where bending of the antenna 3 occurs, contact between the antenna 3 and the insulating cover 4 can be further avoided by the protruding insulating part 5.

### Other Modification Embodiments

The present invention is not limited to the above embodiment.

In the above embodiment, the antenna 3 is an LC antenna including the conductor elements 31, the insulating element 32, and the capacitor 33. However, the antenna 3 is not limited to an LC antenna and may also be other types of antennas.

In the above embodiment, the insulator 51 constituting the protruding insulating part 5 forms an annular shape, but the shape of the insulator 51 is not limited thereto. For example, the insulator 51 may also form a partial annular shape, may also form a protruding shape, or may also be any other shape.

In the above embodiment, in an A-A cross-sectional view, the outer circumferential surface 51a of the insulator 51 has a shape extending along the inner circumferential surface 4a of the insulating cover 4, but is not limited thereto. In the A-A cross-sectional view, the outer circumferential surface 51a of the insulator 51 may also form a protruding shape, a curved shape, or any other shape.

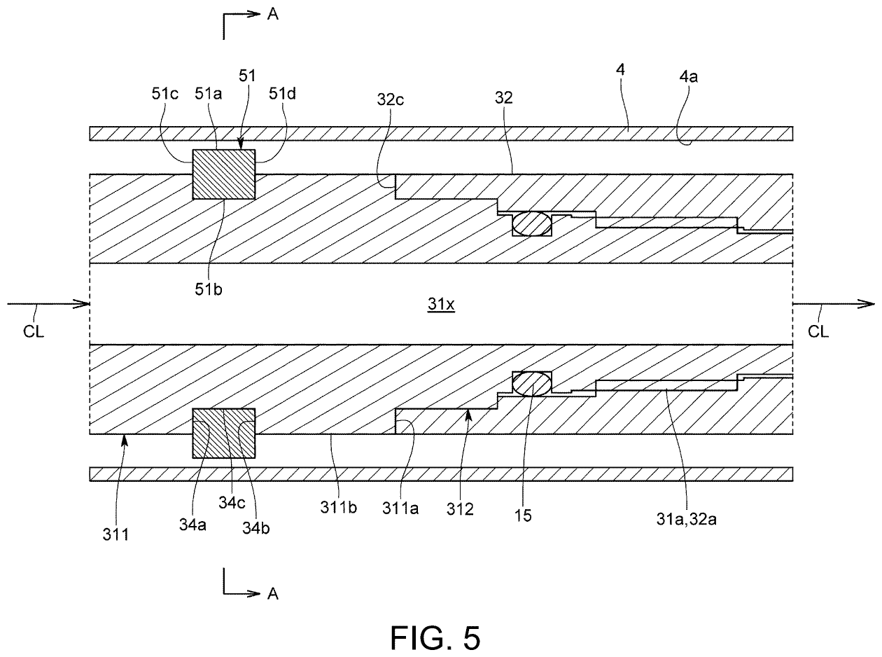

In the above embodiment, the accommodating recess 34 is provided between the axial end face 311a of the metal pipe 31 and the axial end face 32c of the insulating pipe 32, but the position at which the accommodating recess 34 is provided is not limited thereto. For example, as shown in FIG. 5, the accommodating recess 34 may also be formed on the outer circumferential surface 311b of the large-diameter part 311 of the metal pipe 31. Specifically, the accommodating recess 34 is formed on the outer circumferential surface 311b between the axial end face 311a and the other end face of the large-diameter part 311.

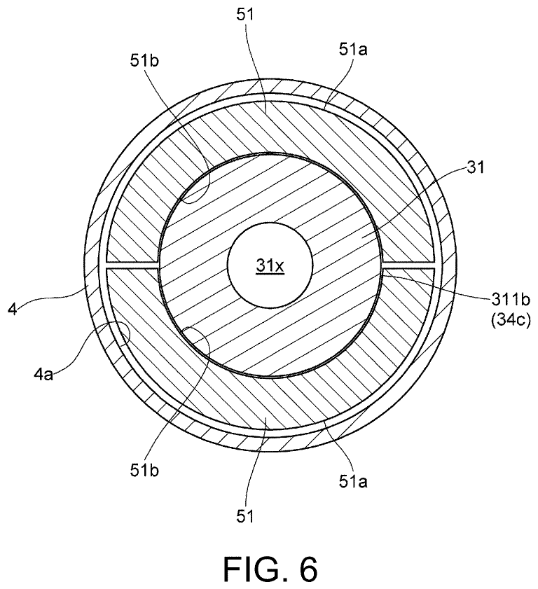

In this case, as shown in FIG. 6, the insulator 51 forms two divided partial annular shapes, and with the two insulators 51 covering to sandwich the accommodating recess 34, the two insulators 51 are attached to the accommodating recess 34. In the state in which the insulator 51 is attached to the accommodating recess 34, the inner circumferential surface 51b of the insulator 51 contacts the outer circumferential surface 311b forming the accommodating recess 34, and the end faces 51c and 51d of the insulator 51 contact the opposing surfaces 34a and 34b of the accommodating recess 34. Accordingly, since the protruding insulating part 5 is separated from the insulating element 32 and is provided in the accommodating recess 34, contact between the protruding insulating part 5 and the insulating element 32 can be prevented, and temperature influence of the protruding insulating part 5 on the insulating element 32 can be suppressed. As a result, since occurrence of a temperature difference in the insulating pipe 32 can be prevented, damage to the insulating pipe 32 can be prevented. In FIG. 6, the quantity of the insulators 51 forming a partial annular shape is two, but may also be three or more, or may also be one.

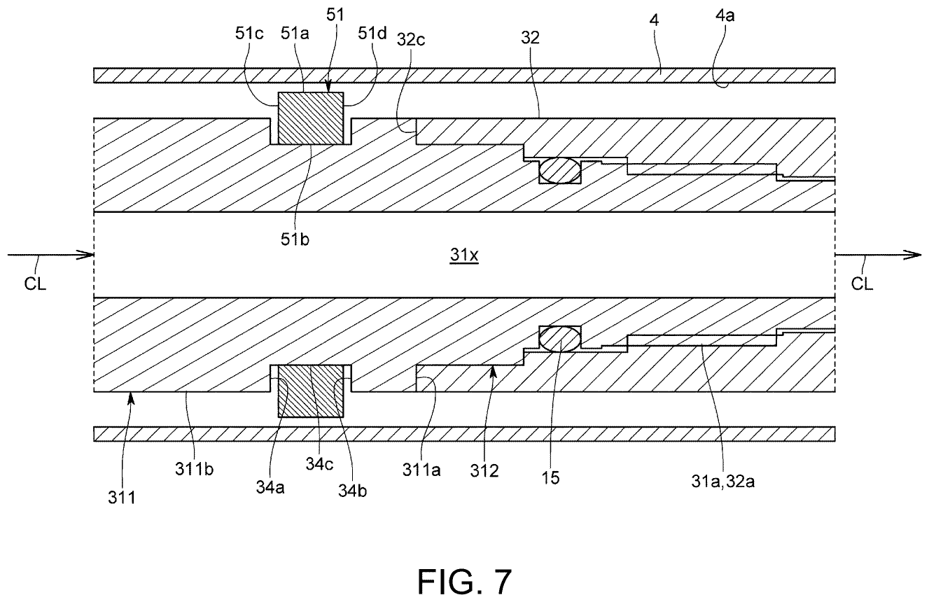

Alternatively, in the case where the accommodating recess 34 is formed on the outer circumferential surface 311b of the large-diameter part 311 of the metal pipe 31, as shown in FIG. 7, the end faces 51c and 51d of the insulator 51 may be provided separated from the opposing surfaces 34a and 34b of the accommodating recess 34. In that case, since the protruding insulating part 5 is provided separated from both the insulating element 32 and the conductor element 31, the temperature influence of the protruding insulating part 5 on the conductor element 31 and the insulating element 32 can be suppressed.

In the above embodiment, the small-diameter part 312 is formed at the conductor pipe 31, and the insertion recess 321 is formed at the insulating pipe 32, but the small-diameter part may also be formed at the insulating pipe 32, and the insertion recess may also be formed at the conductor pipe 31.

In addition, the metal pipes and the insulating pipe form a tubular shape having one internal flow path, but may also have two or more internal flow paths, or may also have branched internal flow paths. In addition, the metal pipes and the insulating pipe may also be solid.

In the electrode of the above embodiment, the extension part is in a cylindrical shape, but may also be in other prismatic tubular shapes, or may be in a flat plate shape, or a curved or bent plate shape.

Obviously, the present invention is not limited to the above embodiments, and various modifications are possible within the scope that does not deviate from the spirit thereof.

### INDUSTRIAL APPLICABILITY

According to the present invention, even in the case of lengthening an antenna to perform plasma processing, damage to an insulating cover can be prevented.

### REFERENCE SIGNS LIST

100: plasma processing device
10: antenna device
W: substrate
P: inductively coupled plasma
2: vacuum vessel
3: antenna
31: metal pipe (conductor element)
32: insulating pipe (insulating element)
33: capacitor
33A: first electrode
34: accommodating recess
4: insulating cover
5: protruding insulating part
51: insulator
CL: cooling liquid (liquid dielectric)

1. An antenna device for flowing a high-frequency current to generate plasma, the antenna device comprising:
an antenna forming a straight line shape;
an insulating cover covering an outer circumferential surface of the antenna and forming a straight tube shape; and
a protruding insulating part provided between both axial ends of the antenna, protruding to an inner circumferential surface side of the insulating cover beyond the outer circumferential surface of the antenna, and is composed of an insulating material.

2. The antenna device according to claim 1, wherein the antenna further comprises:
at least two conductor elements;
an insulating element provided between the conductor elements adjacent to each other to insulate the conductor elements; and
a capacitive element electrically connected in series with the conductor elements adjacent to each other.

3. The antenna device according to claim 2, wherein
an accommodating recess accommodating an insulator constituting the protruding insulating part is formed on the outer circumferential surface of the antenna.

4. The antenna device according to claim 3, wherein
the accommodating recess is formed between an axial end face of the conductor element and an axial end face of the insulating element.

5. The antenna device according to claim 3, wherein
the accommodating recess is formed on an outer circumferential surface of the conductor element.

6. A plasma processing device comprising:
the antenna device according to claim 1;
a vacuum vessel inside which or outside which the antenna is disposed; and
a high-frequency power supply applying a high-frequency current to the antenna.
